(19) United States
(12) Patent Application Publication
(10) Pub. No.: US 2016/0148877 A1
(43) Pub. Date: May 26, 2016

(54) QFN PACKAGE WITH IMPROVED CONTACT PINS

(71) Applicant: MICROCHIP TECHNOLOGY INCORPORATED, Chandler, AZ (US)

(72) Inventors: Rangsun Kitnarong, Bangkeng Muang (TH); Prachit Punyapor, Amphur Thanyaburi (TH); Watcharapong Nokdee, Amphur Muang (TH)

(73) Assignee: MICROCHIP TECHNOLOGY INCORPORATED, Chandler, AZ (US)

(21) Appl. No.: 14/946,024

(22) Filed: Nov. 19, 2015

Related U.S. Application Data
(60) Provisional application No. 62/082,338, filed on Nov. 20, 2014.

(51) Int. Cl. H01L 23/544; H01L 21/48; H01L 21/66; H01L 23/498; H01L 23/31

(52) U.S. Cl. CPC H01L 23/544; H01L 23/49838; H01L 23/3114; H01L 22/12; H01L 21/4889; H01L 21/4842; H01L 21/4839; H01L 2223/5446

(57) ABSTRACT

According to an embodiment of the present disclosure, a method for manufacturing an integrated circuit (IC) device may include mounting an IC chip onto a center support structure of a leadframe, bonding the IC chip to at least some of the plurality of pins, encapsulating the leadframe and bonded IC chip, sawing a step cut into the encapsulated leadframe, plating the exposed portion of the plurality of pins, and cutting the IC package free from the bar. The leadframe may include a plurality of pins extending from the center support structure and a bar connecting the plurality of pins remote from the center support structure. The step cut may be sawn into the encapsulated leadframe along a set of cutting lines using a first saw width without separating the bonded IC package from the bar, thereby exposing at least a portion of the plurality of pins. The IC package may be cut free from the bar by sawing through the encapsulated lead frame at the set of cutting lines using a second saw width less than the first saw width.

### RELATED PATENT APPLICATION

This application claims priority to commonly owned U.S. Provisional Patent Application No. 62/082,338, filed Nov. 20, 2014, which is hereby incorporated by reference herein for all purposes.

### TECHNICAL FIELD

The present disclosure relates to integrated circuit packaging, in particular to so-called flat no-leads packaging for integrated circuits.

### BACKGROUND

Flat no-leads packaging refers to a type of integrated circuit (IC) packaging with integrated pins for surface mounting to a printed circuit board (PCB). Flat no-leads may sometimes be called micro leadframes (MLF). Flat no-leads packages, including for example quad-flat no-leads (QFN) and dual-flat no-leads (DFN), provide physical and electrical connection between an encapsulated IC component and an external circuit (e.g., to a printed circuit board (PCB)).

In general, the contact pins for a flat no-leads package do not extend beyond the edges of the package. The pins are usually formed by a single leadframe that includes a central support structure for the die of the IC. The leadframe and IC are encapsulated in a housing, typically made of plastic. Each leadframe may be part of a matrix of leadframes that has been molded to encapsulate several individual IC devices. Usually, the matrix is sawed apart to separate the individual IC devices by cutting through any joining members of the leadframe. The sawing or cutting process also exposes the contact pins along the edges of the packages.

Once sawn, the bare contact pins may provide bad or no connection for reflow soldering. The exposed face of contact pins may not provide sufficient wettable flanks to provide a reliable connection. Reflow soldering is a preferred method for attaching surface mount components to a PCB, intended to melt the solder and heat the adjoining surfaces without overheating the electrical components, and thereby reducing the risk of damage to the components.

### SUMMARY

Hence, a process or method that improves the wettable surface of flat no-leads contact pins for a reflow soldering process to mount the flat no-leads package to an external circuit may provide improved electrical and mechanical performance of an IC in a QFN or other flat no-leads package.

According to an embodiment of the present disclosure, a method for manufacturing an integrated circuit (IC) device may include mounting an IC chip onto a center support structure of a leadframe, bonding the IC chip to at least some of the plurality of pins, encapsulating the leadframe and bonded IC chip, sawing a step cut into the encapsulated leadframe, plating the exposed portion of the plurality of pins, and cutting the IC package free from the bar. The leadframe may include a plurality of pins extending from the center support structure and a bar connecting the plurality of pins remote from the center support structure. The step cut may be sawn into the encapsulated leadframe along a set of cutting lines using a first saw width without separating the bonded IC package from the bar, thereby exposing at least a portion of the plurality of pins. The IC package may be cut free from the bar by sawing through the encapsulated lead frame at the set of cutting lines using a second saw width less than the first saw width.

According to a further embodiment, a method for installing an integrated circuit (IC) device on a printed circuit board (PCB) may include mounting an IC chip onto a center support structure of a leadframe, bonding the IC chip to at least some of the plurality of pins, encapsulating the leadframe and bonded IC chip, sawing a step cut into the encapsulated leadframe, plating the exposed portion of the plurality of pins, cutting the IC package free from the bar, and attaching the flat no-leads IC package to the PCB. The leadframe may include a plurality of pins extending from the center support structure and a bar connecting the plurality of pins remote from the center support structure. The step cut may be sawn along a set of cutting lines using a first saw width without separating the bonded IC package from the bar, thereby exposing at least a portion of the plurality of pins. The IC package may be cut free from the bar by sawing through the encapsulated lead frame at the set of cutting lines using a second saw width less than the first saw width. The IC package may be attached to the PCB using a reflow soldering method to join the plurality of pins of the IC package to respective contact points on the PCB.

According to a further embodiment, an integrated circuit (IC) device in a flat no-lead package may include an IC chip mounted onto a center support structure of a leadframe and encapsulated with the leadframe to form an IC package having a bottom face and four sides. The IC device may include a set of pins with faces exposed along a lower edge of the four sides of the IC package. The IC device may include a step cut into the IC package along a perimeter of the bottom face of the IC package, including the exposed faces of the set of pins. A bottom facing exposed portion of the plurality of pins including the step cut may be plated.

### BRIEF DESCRIPTION OF THE DRAWINGS

FIG. 1 is a schematic showing a cross section side view through an embodiment a flat no-leads package mounted on a printed circuit board (PCB) according to the teachings of the present disclosure.

FIG. 2A is a picture showing part of a typical QFN package in a side view and bottom view. FIG. 2B shows an enlarged view of the face of copper contact pins along the edge of QFN package exposed by sawing through an encapsulated leadframe.

FIG. 3 is a picture showing a typical QFN package after a reflow soldering process failed to provide sufficient mechanical and electrical connections to a PCB.

FIGS. 4A and 4B are pictures showing a partial view of a packaged IC device incorporating teachings of the present disclosure in a flat no-leads package with high wettable flanks for use in reflow soldering.

FIG. 5A is a picture of the packaged IC device of FIG. 4 after a reflow soldering process provided an improved solder connection; FIG. 5B is a drawing showing an enlarged detail of the improved solder connection.

FIG. 6 is a drawing showing a top view of a leadframe which may be used to practice the teachings of the present disclosure.

FIG. 7 is a flowchart illustrating an example method for manufacturing an integrated circuit (IC) device in a flat no-leads package incorporating teachings of the present disclosure.

FIGS. 8A-8C are schematic drawings illustrating part of an example method for manufacturing an integrated circuit (IC) device in a flat no-leads package incorporating teachings of the present disclosure.

FIGS. 8D and 8E are pictures of an IC device package after the process step of FIGS. 8A-8C has been completed.

FIG. 9A is a schematic drawing illustrating part of an example method for manufacturing an integrated circuit (IC) device in a flat no-leads package incorporating teachings of the present disclosure.

FIGS. 9B and 9C are pictures of an IC device package after the process step of FIG. 9A has been completed.

FIGS. 10A and 10B are schematic drawings illustrating part of an example method for manufacturing an integrated circuit (IC) device in a flat no-leads package incorporating teachings of the present disclosure.

FIG. 10C is a picture of an IC device package after the process step of FIGS. 10A and 10B have been completed.

FIGS. 11A and 11B are schematic drawings illustrating part of an example method for manufacturing an integrated circuit (IC) device in a flat no-leads package incorporating teachings of the present disclosure.

FIG. 11C is a picture of an IC device package after the process step of FIGS. 11A and 11B have been completed.

### DETAILED DESCRIPTION

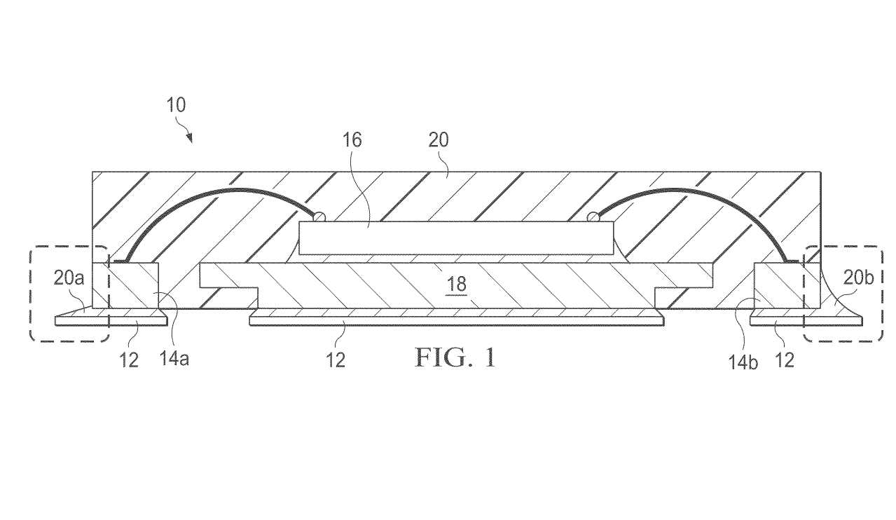

FIG. 1 is a side view showing a cross section view through a flat no-leads package 10 mounted on a printed circuit board (PCB) 12. Package 10 includes contact pins 14a, 14b, die 16, leadframe 18, and encapsulation 20. Die 16 may include any integrated circuit, whether referred to as an IC, a chip, and/or a microchip. Die 16 may include a set of electronic circuits disposed on a substrate of semiconductor material, such as silicon.

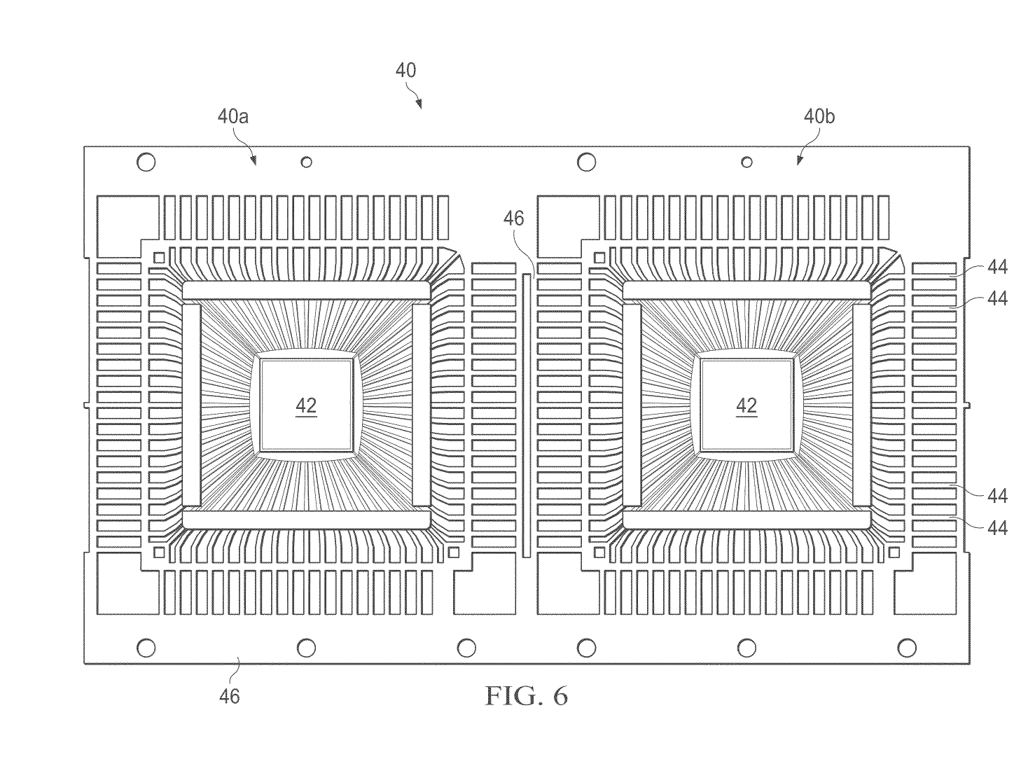

As shown in FIG. 1, contact pin 14a is the subject of a failed reflow process in which the solder 20a did not stay attached to the exposed face of contact pin 14a; the bare copper face of contact pin 14a created by sawing the package 10 free from a leadframe matrix (shown in more detail in FIG. 6 and discussed below) may contribute to such failures. In contrast, contact pin 14b shows an improved soldered connection 20b created by a successful reflow procedure. This improved connection provides both electrical communication and mechanical support. The face of contact pin 14b may have been plated before the reflow procedure (e.g., with tin plating).

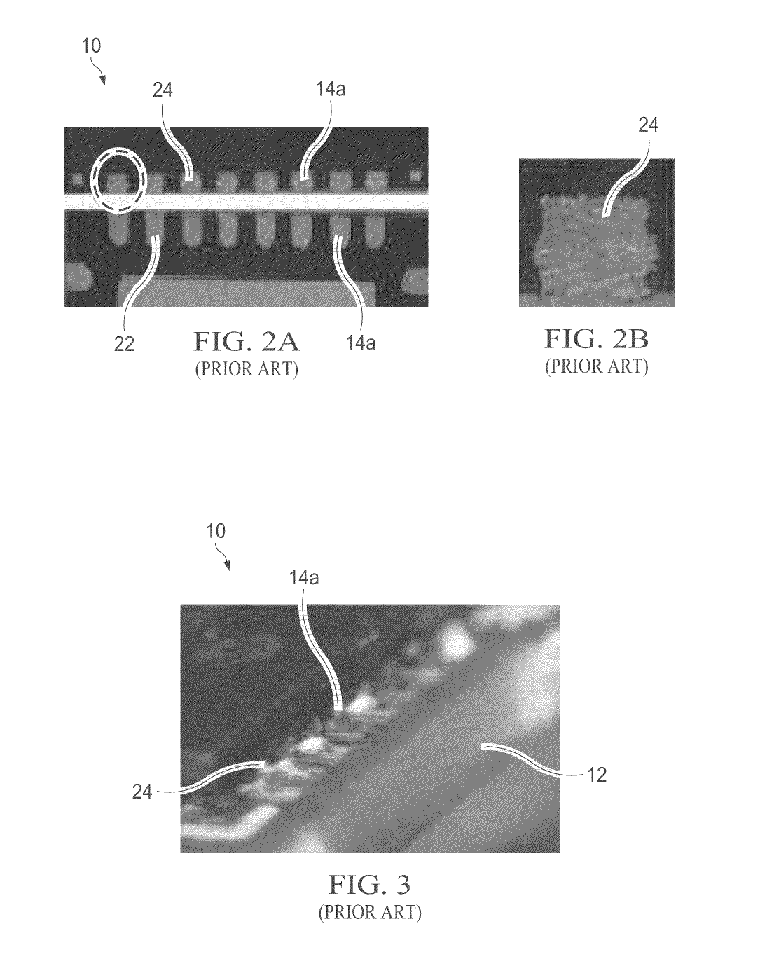

FIG. 2A is a picture showing part of a typical QFN package 10 in a side view and bottom view. FIG. 2B shows an enlarged view of the face 24 of copper contact pins 14a along the edge of QFN package 10 exposed by sawing through the encapsulated leadframe 18. As shown in FIG. 2A, the bottom 22 of contact pin 14a is plated (e.g., with tin plating) but the exposed face 24 is bare copper.

FIG. 3 is a picture of a typical QFN package 10 after a reflow soldering process failed to provide sufficient mechanical and electrical connections to a PCB 12. As shown in FIG. 3, bare copper face 24 of contact pins 14a may provide bad or no connection after reflow soldering. The exposed face 24 of contact pins 14a may not provide sufficient wettable flanks to provide a reliable connection.

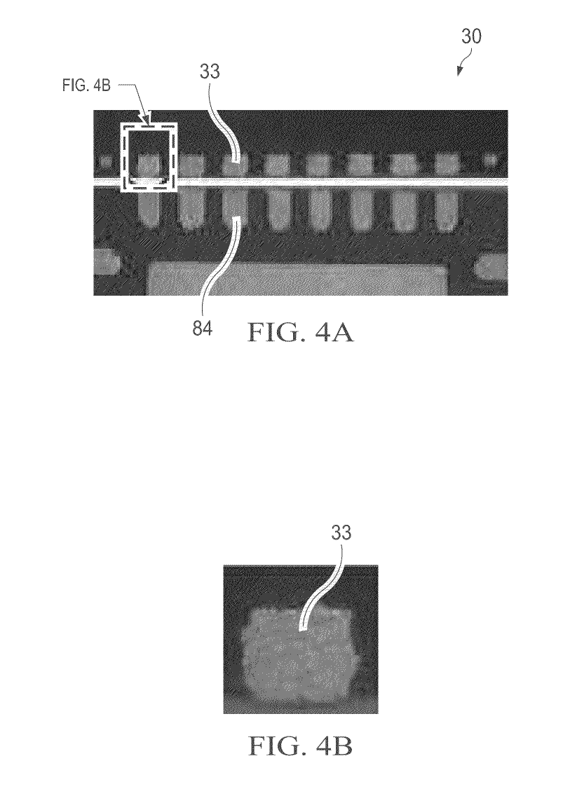

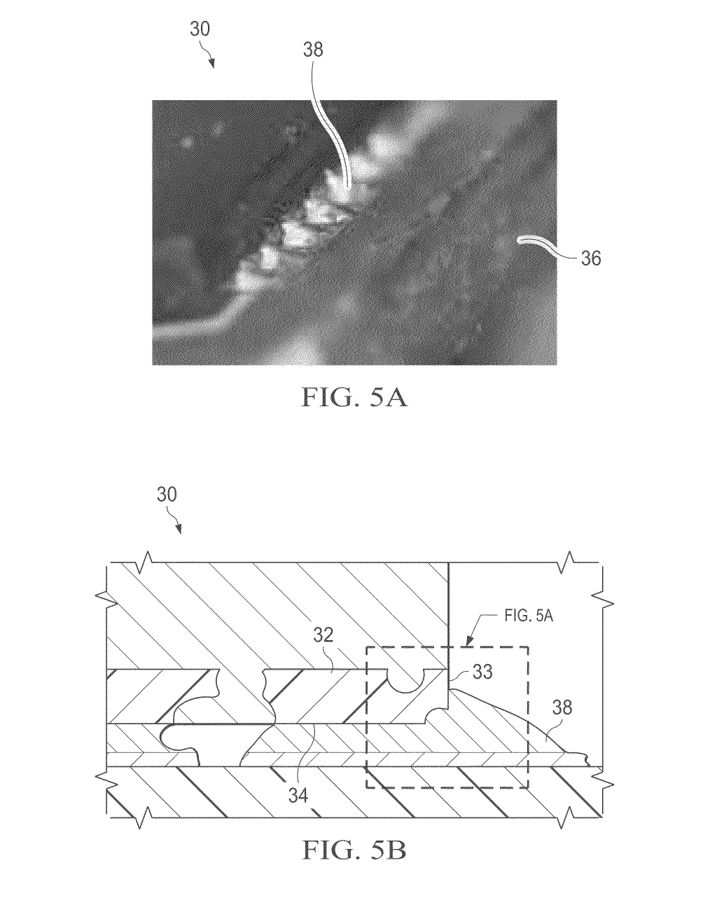

FIGS. 4A and 4B are pictures showing a partial view of a packaged IC device 30 incorporating the teachings of the present disclosure wherein both the exposed face portion 33 and the bottom surface 34 of the pins 32 have been plated with tin to produce an IC device 30 in a flat no-leads package with high wettable flanks for use in reflow soldering, providing an improved solder connection as shown at contact pin 14b in FIG. 1 and demonstrated in the picture of FIG. 5. As shown, IC device 30 may comprise a quad-flat no-leads packaging. In other embodiments, IC device 30 may comprise a dual-flat no-leads packaging, or any other packaging (e.g., any micro leadframe (MLT)) in which the leads do not extend much beyond the edges of the packaging and which is configured to surface-mount the IC to a printed circuit board (PCB).

FIG. 5A is a picture showing packaged IC device 30 with plating on both exposed face portion 33 of the pins 32 and the bottom surface 34 of pins 32, demonstrating the improved connection after a reflow soldering process connecting to a PCB 36. FIG. 5B is a drawing showing an enlarged cross-sectional detail of IC device 30 after attachment to PCB 36 using a reflow soldering process. As visible in FIGS. 5A and 5B, solder 38 is connected to pins 32 along both the bottom surface 34 and the face portion 33.

FIG. 6 shows a leadframe 40 which may be used to practice the teachings of the present disclosure. As shown, leadframe 40 may include a center support structure 42, a plurality of pins 44 extending from the center support structure, and one or more bars 46 connecting the plurality of pins remote from the center support structure. Leadframe 40 may include a metal structure providing electrical communication through the pins 44 from an IC device (not shown in FIG. 6) mounted to center support structure 42 as well as providing mechanical support for the IC device. In some applications, an IC device may be glued to center support structure 42. In some embodiments, the IC device may be referred to as a die. In some embodiments, pads or contact points on the die or IC device may be connected to respective pins by bonding (e.g., wire bonding, ball bonding, wedge bonding, compliant bonding, thermosonic bonding, or any other appropriate bonding technique). In some embodiments, leadframe 40 may be manufactured by etching or stamping. Leadframe 40 may be part of a matrix of leadframes 40a, 40b for use in batch processing.

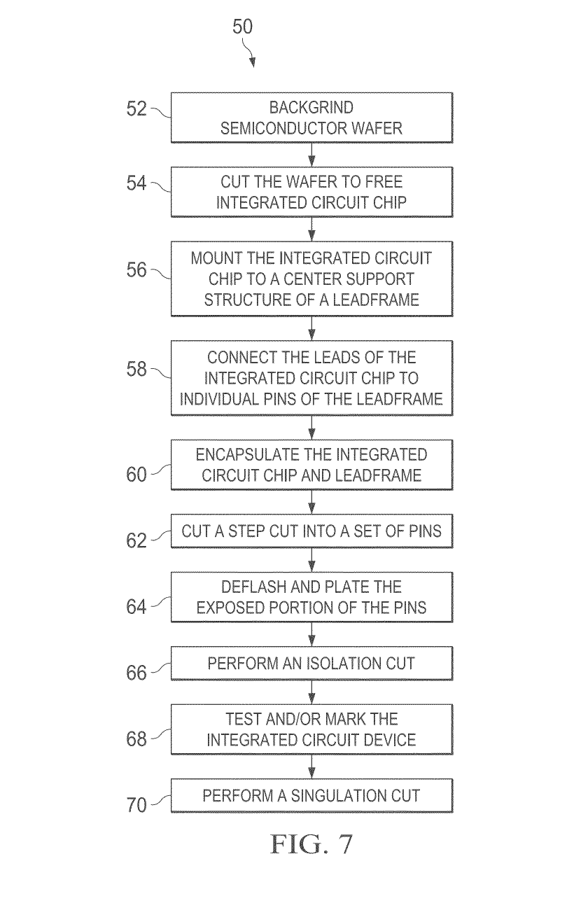

FIG. 7 is a flowchart illustrating an example method 50 for manufacturing an integrated circuit (IC) device in a flat no-leads package incorporating teachings of the present disclosure. Method 50 may provide improved connection for mounting the IC device to a PCB.

Step 52 may include backgrinding a semiconductor wafer on which an IC device has been produced. Typical semiconductor or IC manufacturing may use wafers approximately 750 μm thick. This thickness may provide stability against warping during high-temperature processing. In contrast, once the IC device is complete, a thickness of approximately 50 μm to 75 μm may be preferred. Backgrinding (also called backlap or wafer thinning) may remove material from the side of the wafer opposite the IC device.

Step 54 may include sawing and/or cutting the wafer to separate the IC device from other components formed on the same wafer.

Step 56 may include mounting the IC die (or chip) on a center support structure of a leadframe. The IC die may be attached by the center support structure by gluing or any other appropriate method.

At Step 58, the IC die may be connected to the individual pins extending from the center support structure of the leadframe. In some embodiments, pads and/or contact points on the die or IC device may be connected to respective pins by bonding (e.g., wire bonding, ball bonding, wedge bonding, compliant bonding, thermosonic bonding, or any other appropriate bonding technique).

At Step 60, the IC device and leadframe may be encapsulated to form an assembly. In some embodiments, this includes molding into a plastic case. If a plastic molding is used, a post-molding cure step may follow to harden and/or set the housing.

At Step 62, a step cut may be sawn into the encapsulated assembly. The step cut may be made along a set of cutting lines selected to cross at least a set of pins of the leadframe. The step cut may be made using a step cut saw width. In some embodiments, the step cut saw width may be approximately 0.4 mm. In some embodiments, the first step cut may be made approximately 0.1-0.15 mm deep into a leadframe having a thickness of about 0.2 mm. The first step cut does not, therefore, cut all the way through the pins.

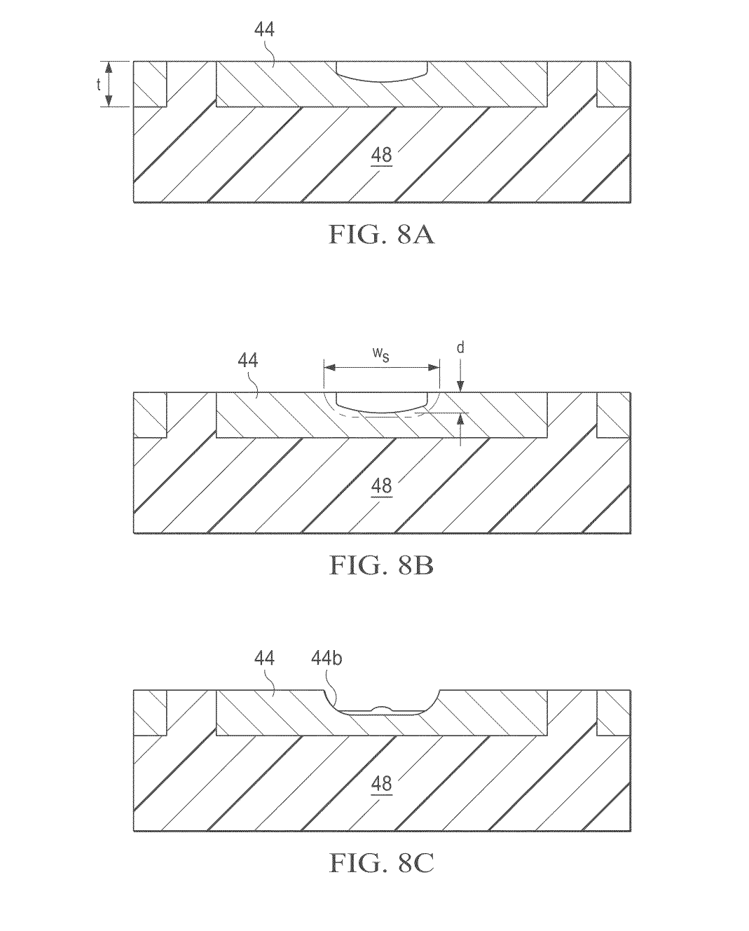

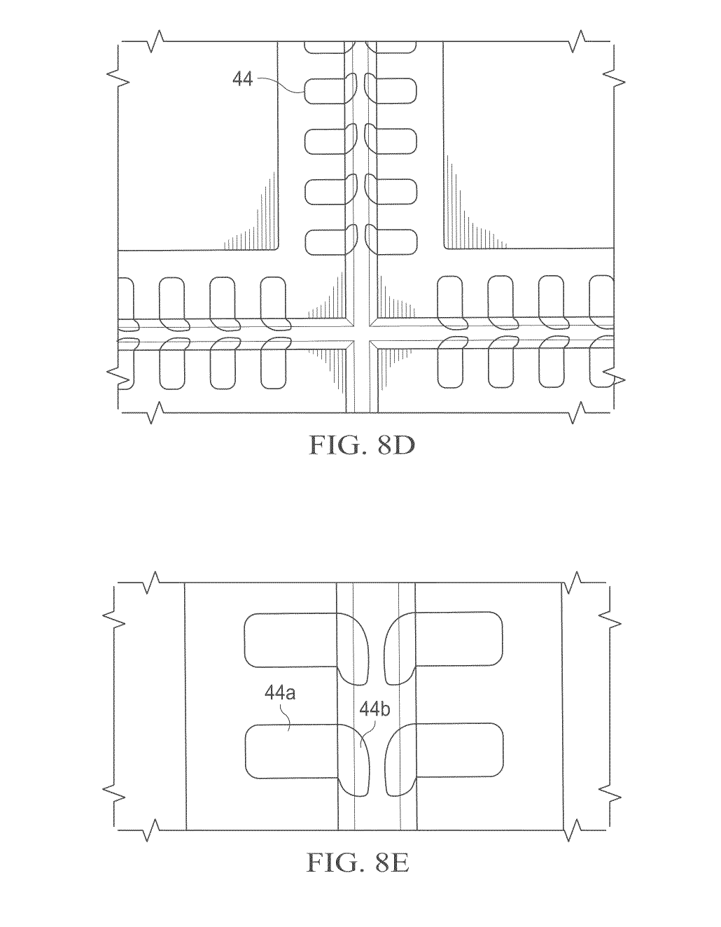

FIG. 8 illustrates a process of one embodiment of a step cut that may be used at Step 62, with FIGS. 8A-8C including schematics showing a side view of Step 62. As shown in FIG. 8A, pins 44 may be encapsulated in a plastic molding 48. Pins 44 and/or any other leads in leadframe 40 may have a thickness, t. As shown in FIG. 8B, the step cut saw width, wₛ, and depth, d, do not fully separate pins 44 from neighboring packages. FIG. 8C shows pins 44 exposed along the bottom surface 44a and step cut 44b. FIGS. 8D and 8E are isometric views showing pins 44 after Step 62 has been completed.

Step 64 may include a chemical de-flashing and a plating process to cover the exposed bottom areas of the connection pins.

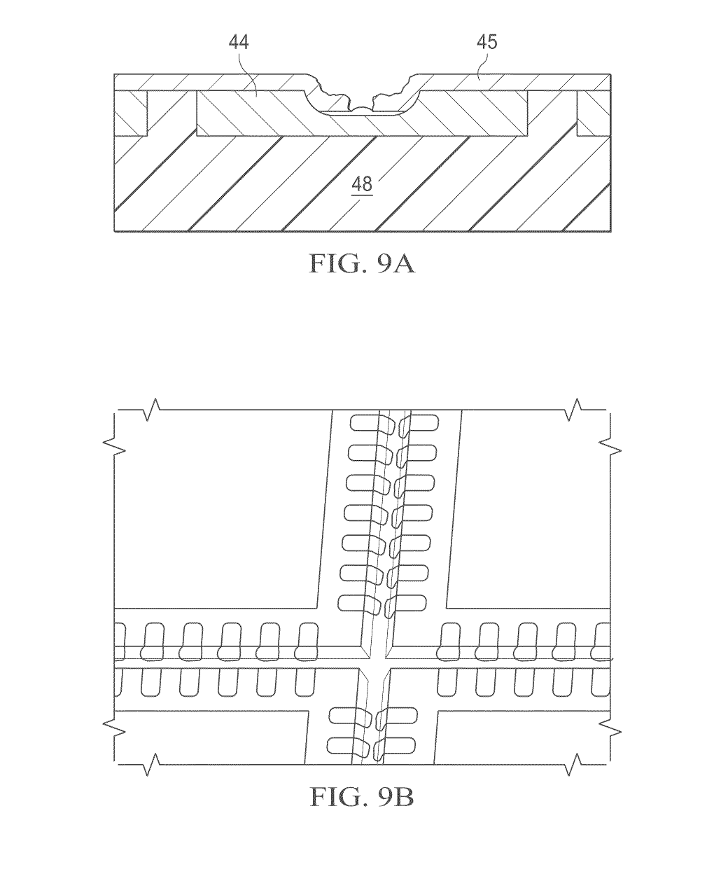

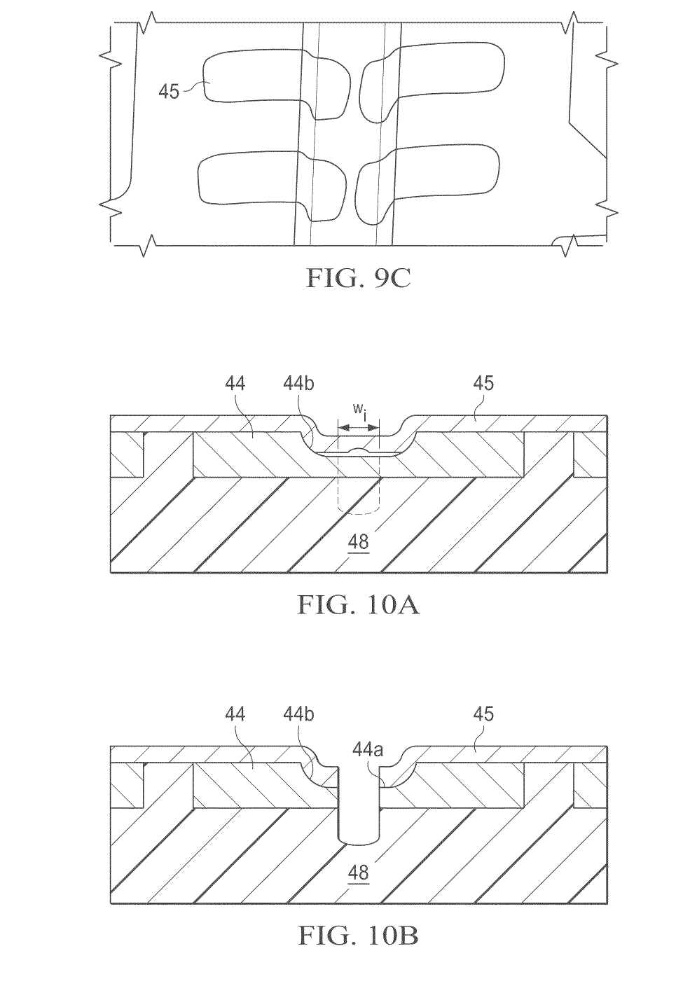

FIG. 9 illustrates the results of one embodiment of a plating process that may be used at Step 64. FIG. 9A is a schematic side view in cross section showing pins 44 encapsulated in plastic molding 48, having a step cut as discussed in relation to Step 62. In addition, plating 45 has been deposited on the exposed surfaces of pins 44, including the bottom surfaces 44a and step cut 44b. FIGS. 9B and 9C are pictures showing plated pins 44.

Step 66 may include performing an isolation cut. The isolation cut may include sawing through the pins of each package to electrically isolate the pins from one another. The isolation cut may be made using a saw width less than the saw width used to make the step cut. In some embodiments, the isolation cut may be made with a blade having a thickness of approximately 0.24 mm.

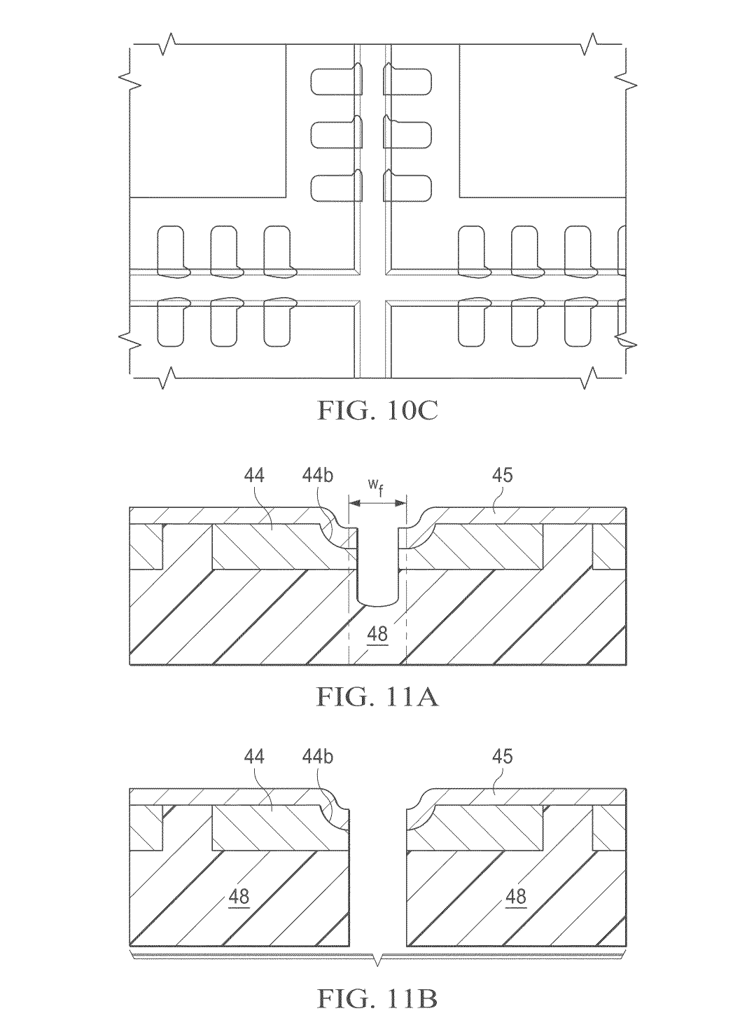

FIG. 10 illustrates a process of one embodiment of an isolating cut that may be used at Step 66. FIGS. 10A and 10B are schematic drawings showing a cross-sectional side view of pins 44 encapsulated in plastic molding 48 and after a step cut and plating of the exposed surfaces. After plating 45 has been deposited in Step 64, an isolation cut of width wᵢ is made beyond the full thickness t of pins 44 as shown in FIG. 10B. wᵢ is narrower than wₛ leaving at least a portion of the plated step cut remaining after the isolation cut. In contrast to Step 62, the depth of the isolation cut is larger than the total thickness t of pins 44 so that the individual pins 44 and circuits of leadframe 40 will no longer be in electrical communication through the matrix of leadframes and/or bar 46. FIG. 10C is a picture showing pins 44 after Step 66 is complete.

Step 68 may include a test and marking of the IC device once the isolation cut has been completed. Method 50 may be changed by altering the order of the various steps, adding steps, and/or eliminating steps. For example, flat no-leads IC packages may be produced according to teachings of the present disclosure without performing an isolation cut and/or testing of the IC device. Persons having ordinary skill in the art will be able to develop alternative methods using these teachings without departing from the scope or intent of this disclosure.

Step 70 may include a singulation cut to separate the IC device from the bar, the leadframe, and/or other nearby IC devices in embodiments where leadframe 40 is part of a matrix of leadframes 40. The singulation cut may include sawing through the same cutting lines as the step cut and/or the isolation cut with a saw width less than the step cut saw width. In some embodiments, the singulation saw width may be approximately 0.3 mm. The singulation cut exposes only a portion of the bare copper of the pins of the leadframe. Another portion of the pins remain plated and unaffected by the final sawing step.

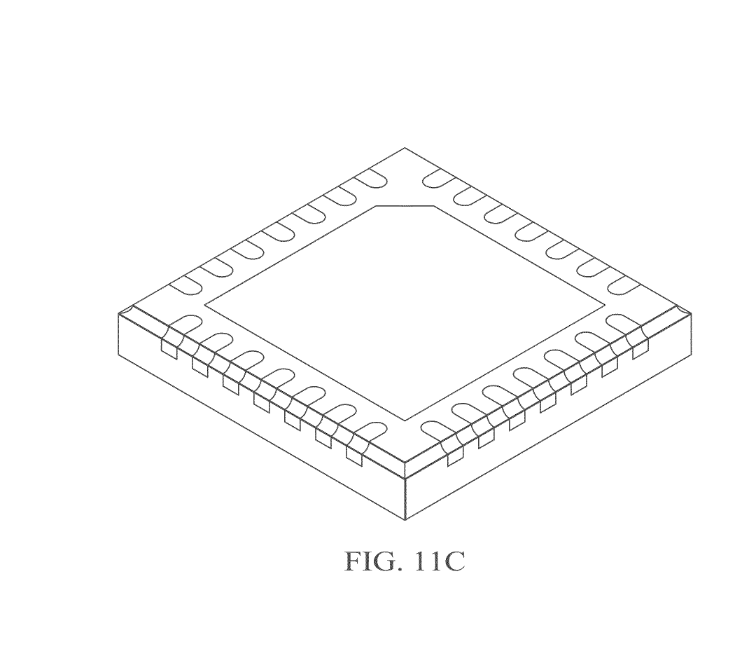

FIG. 11 illustrates a process of one embodiment of a singulation cut that may be used at Step 70. FIGS. 11A and 11B are schematic drawings showing a cross-sectional side view of pins 44 encapsulated in plastic molding 48 and after a step cut, plating of the exposed surfaces, and an isolation cut. After any testing and/or marking in Step 68, a singulation cut of width w_{f} is made through the full package as shown in FIG. 11B. w_{f} is narrower than wₛ leaving at least a portion of the plated step cut remaining after the singulation cut. FIG. 11C is a picture showing pins 44 after Step 66 is complete.

Step 72 may include attaching the separated IC device, in its package, to a PCB or other mounting device. In some embodiments, the IC device may be attached to a PCB using a reflow soldering process. FIG. 5B shows a view of the pin area of an IC device that has been mounted on a printed circuit board and attached by a reflow solder process. The half sawn cut or step cut provided by the present disclosure can increase the wettable flanks or fillet height to 60% and meet, for example, automotive customer requirements. Thus, according to various teachings of the present disclosure, the “wettable flanks” of a flat no-leads device may be improved and each solder joint made by a reflow soldering process may provide improved performance and/or increased acceptance rates during visual and/or performance testing.

In contrast, a conventional manufacturing process for a flat no-leads integrated circuit package may leave pin connections without sufficient wettable surface for a reflow solder process. Even if the exposed pins are plated before separating the package from the leadframe or matrix, the final sawing step used in a typical process leaves only bare copper on the exposed faces of the pins.

1. A method for manufacturing an integrated circuit (IC) device in a flat no-leads package, the method comprising:
mounting an IC chip onto a center support structure of a leadframe, the leadframe including:
a plurality of pins extending from the center support structure; and
a bar connecting the plurality of pins remote from the center support structure;
bonding the IC chip to at least some of the plurality of pins;
encapsulating the leadframe and bonded IC chip;
sawing a step cut into the encapsulated leadframe along a set of cutting lines using a first saw width without separating the bonded IC package from the bar, thereby exposing at least a portion of the plurality of pins;
plating the exposed portion of the plurality of pins; and
cutting the IC package free from the bar by sawing through the encapsulated lead frame at the set of cutting lines using a second saw width less than the first saw width.

2. A method according to claim 1, further comprising:
performing an isolation cut to isolate individual pins of the IC package without separating the IC package from the lead frame; and
performing a circuit test of the isolated individual pins after the isolation cut.

3. A method according to claim 1, further comprising:
performing an isolation cut to isolate individual pins of the IC package without separating the IC package from the lead frame, wherein the isolation cut is performed with a third saw width less than the first saw width; and
performing a circuit test of the isolated individual pins after the isolation cut.

4. A method according to claim 1, further comprising bonding the IC chip to at least some of the plurality of pins using wire bonding.

5. A method according to claim 1, wherein the first saw width is approximately 0.40 mm.

6. A method according to claim 1, wherein the second saw width is approximately 0.30 mm.

7. A method according to claim 3, wherein the third saw width is approximately between 0.24 mm and 0.30 mm.

8. A method according to claim 1, wherein the step cut is approximately 0.1 mm to 0.15 mm deep and the leadframe has a thickness of approximately 0.20 mm.

9. A method for installing an integrated circuit (IC) device in a flat no-leads package onto a printed circuit board (PCB), the method comprising:
mounting an IC chip onto a center support structure of a leadframe, the leadframe including:
a plurality of pins extending from the center support structure; and
a bar connecting the plurality of pins remote from the center support structure;
bonding the IC chip to at least some of the plurality of pins;
encapsulating the leadframe and bonded IC chip;
sawing a step cut into the encapsulated leadframe along a set of cutting lines using a first saw width without separating the bonded IC package from the bar, thereby exposing at least a portion of the plurality of pins;
plating the exposed portion of the plurality of pins;
cutting the IC package free from the bar by sawing through the encapsulated lead frame at the set of cutting lines using a second saw width less than the first saw width; and
attaching the flat no-leads IC package to the PCB using a reflow soldering method to join the plurality of pins of the IC package to respective contact points on the PCB.

10. A method according to claim 9, further comprising:
performing an isolation cut to isolate individual pins of the IC package without separating the IC package from the bar; and
performing a circuit test of the isolated individual pins after the isolation cut.

11. A method according to claim 9, further comprising:
performing an isolation cut to isolate individual pins of the IC package without separating the IC package from the bar, wherein the isolation cut is performed with a third saw width less than the first saw width; and
performing a circuit test of the isolated individual pins after the isolation cut.

12. A method according to claim 9, further comprising bonding the IC chip to at least some of the plurality of pins using wire bonding.

13. A method according to claim 9, wherein the first saw width is approximately 0.40 mm.

14. A method according to claim 9, wherein the second saw width is approximately 0.30 mm.

15. A method according to claim 11, wherein the third saw width is approximately between 0.24 mm and 0.30 mm.

16. A method according to claim 9, wherein the step cut is approximately 0.1 mm to 0.15 mm deep and the leadframe has a thickness of approximately 0.20 mm.

17. A method according to claim 9, wherein the reflow soldering process provides fillet heights of approximately 60% of the exposed surface of the pins.

18. An integrated circuit (IC) device in a flat no-leads package comprising:
an IC chip mounted onto a center support structure of a leadframe and encapsulated with the leadframe to form an IC package having a bottom face and four sides;
a set of pins with faces exposed along a lower edge of the four sides of the IC package; and
a step cut into the IC package along a perimeter of the bottom face of the IC package, including the exposed faces of the set of pins;
wherein a bottom facing exposed portion of the plurality of pins including the step cut is plated.

19. An IC device according to claim 18, wherein the step cut is approximately 0.10 mm to 0.15 mm deep.

20. An IC device according to claim 18, wherein the plurality of pins are attached to a printed circuit board with fillet heights of approximately 60%.
